(19) United States
(12) Patent Application Publication
(10) Pub. No.: US 2007/0254417 A1
(43) Pub. Date: Nov. 1, 2007

(54) METHOD OF FABRICATING A SEMICONDUCTOR DEVICE HAVING A CAPACITOR

(75) Inventors: Jung-Ching Chen, Taichung County (TW); Chin-Hung Liu, Taipei County (TW); Chien-Ming Lin, Hsinchu City (TW); Ming-Tsung Tung, Hsinchu (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: United Microelectronics Corp., Hsinchu (TW)

(21) Appl. No.: 11/777,294

(22) Filed: Jul. 13, 2007

Related U.S. Application Data
(62) Division of application No. 11/306,162, filed on Dec. 19, 2005.

(51) Int. Cl. H01L 21/8242; H01L 21/20

(52) U.S. Cl. 438/155; 438/251; 438/396; 257/E21.09; 257/E21.646

(57) ABSTRACT

A semiconductor device having a capacitor is provided. The semiconductor device includes a substrate, a capacitor and a metal-oxide-semiconductor (MOS) transistor. The MOS transistor is located in a MOS transistor region of the substrate, and the MOS transistor region has a first bottom diffusion region. The capacitor is located in a capacitor region of the substrate and consisted of a second bottom diffusion region located in the substrate, a first dielectric layer located over the second bottom diffusion region, a bottom conductive layer located over the first dielectric layer, a second dielectric layer located over the bottom conductive layer, and a top conductive layer located over the second dielectric layer. The first bottom diffusion region and the second bottom diffusion region are different conductive type.

### CROSS-REFERENCE TO RELATED APPLICATION

This application is a divisional of an application Ser. No. 11/306,162, filed on Dec. 19, 2005, now pending. The entirety of the above-mentioned patent application is hereby incorporated by reference herein and made a part of this specification.

### BACKGROUND OF THE INVENTION

1. Field of the Invention

The present invention relates to a semiconductor device structure and a fabricating method thereof. More particularly, the present invention relates to a semiconductor device having a capacitor and the fabricating method thereof.

2. Description of the Related Art

Dynamic random access memory (DRAM) mainly includes MOS transistors and capacitors. The structure of capacitor is normally grouped into two major kinds namely, the stack capacitor and the deep trench capacitor. In general, the stack capacitor can be further sub-divided into the conventional metal-insulator-metal (MIM) capacitor and the MOS capacitor. The MOS capacitor has a structure comprising a gate-insulator-gate (that is, polysilicon-insulator-polysilicon) capacitor disposed on a shallow trench isolation (STI) structure.

FIG. 1 is a schematic cross-sectional view of a conventional capacitor. As shown in FIG. 1, the substrate 100 has a shallow trench isolation (STI) structure 102. This type of capacitor 110 is formed on the STI structure 102. The capacitor 110 comprises two polysilicon layers 104 and 108 and a dielectric layer 106 sandwiched between the polysilicon layers 104 and 106. An inter-layer dielectric (ILD) layer 112 covers the capacitor 110. Furthermore, a pair of contacts 114 and 116 within the ILD layer 112 is connected to the polysilicon layers 104 and 108 respectively.

However, as technological progress leads semiconductor fabrication into the deep sub-micro generation, the dimension of each semiconductor device shrinks substantially so that the area occupied by each capacitor must be reduced. As a result, difficulties are often encountered in attempts for increasing the capacitance of a capacitor. On the other hand, the ever-increasing size of computer application software often renders the use of memory with a large storage capacity essential. Since the storage capacitor of a memory is closely related to the capacitance of the capacitor, the conflicting demand for a smaller capacitor size but a higher capacitance results in an urgent need for changing the way in which the dynamic random access memory capacitors are fabricated.

### SUMMARY OF THE INVENTION

Accordingly, at least one objective of the present invention is to provide a semiconductor device having a capacitor and the method of fabricating the same such that a different capacitance can be obtained by setting the thickness of a dielectric layer and the MOS transistor Vt can free from the influence of the voltage provided to the capacitor. Furthermore, it doesn't need other mask to form the capacitor of the present invention.

At least another objective of the present invention is to provide an insulator-on-silicon semiconductor capacitor and the fabricating method thereof that can obtain a large capacitance and a small area to save more design area.

At least yet another objective of the present invention is to provide a capacitor for a semiconductor device and the fabricating method thereof that can save some space in the device.

To achieve these and other advantages and in accordance with the purpose of the invention, as embodied and broadly described herein, the invention provides a semiconductor device having a capacitor therein. The semiconductor device comprises a substrate, a capacitor and a metal-oxide-semiconductor (MOS) transistor. The MOS transistor is located in a MOS transistor region of the substrate, and the MOS transistor region has a first bottom diffusion region. The capacitor is located in a capacitor region of the substrate and consisted of a second bottom diffusion region, a first dielectric layer, a bottom conductive layer, a second dielectric layer, a top conductive layer, wherein the second bottom diffusion region and the first bottom diffusion region are different conductive type. The second bottom diffusion region is located in the substrate. The first dielectric layer is located over the second bottom diffusion region. The bottom conductive layer is located over the first dielectric layer. The second dielectric layer is located over the bottom conductive layer. The top conductive layer located over the second dielectric layer.

According to the aforesaid semiconductor device with capacitor therein in the embodiment of the present invention, the second bottom diffusion region is an N-well and the first bottom diffusion region is a P-well, for example. The semiconductor device further includes a isolation structure located in the substrate to separate the MOS transistor region and the capacitor region.

According to the aforesaid semiconductor device with capacitor therein in the embodiment of the present invention, the bottom conductive layer and the top conductive layer can be fabricated using polysilicon.

According to the aforesaid semiconductor device with capacitor therein in the embodiment of the present invention, the first dielectric layer and the second dielectric layer can be an oxide layer, a silicon nitride layer or an oxide/nitride/oxide (ONO) layer.

According to the aforesaid semiconductor device with capacitor therein in the embodiment of the present invention, the semiconductor device further includes a contact region in the second bottom diffusion region, an inter-layer dielectric (ILD) layer located over the substrate to cover the capacitor and a plurality of contacts in the ILD layer that connects with the bottom conductive layer, the top conductive layer and the contact region respectively.

The present invention also provides a method of fabricating a semiconductor device with a capacitor therein. First, a substrate is provided. The substrate has a capacitor region and a MOS transistor region. Then, a first bottom diffusion region and a second bottom diffusion region are formed in the substrate within the MOS transistor region and the capacitor region respectively, wherein the second bottom diffusion region and the first bottom diffusion region are different conductive type. Thereafter, a first dielectric layer is formed over the substrate and then a first conductive layer is formed over the first dielectric layer. After that, a patterned mask layer is formed over the first conductive layer to expose the MOS transistor region and a portion of the first conductive layer in the capacitor region. Then, using the patterned mask layer as a mask, the exposed first conductive layer is removed so that only the bottom conductive layer in the capacitor region is retained. Again using the patterned mask layer as a mask, a threshold voltage (Vt) adjustment implant process is performed. The patterned mask layer is removed. A second dielectric layer is formed on the surface of the substrate and the bottom conductive layer. Then, a second conductive layer is formed over the second dielectric layer. The second conductive layer is patterned to define the top conductive layer of the capacitor region and the gate of the MOS transistor region. The second bottom diffusion region, the first dielectric layer, the bottom conductive layer, the second dielectric layer and the top conductive layer together form a capacitor.

According to the aforesaid method of fabricating a semiconductor device with a capacitor therein in the embodiment of the present invention, after patterning the second conductive layer, further includes performing an ion implant process to form a contact region in the second bottom diffusion region beside the capacitor and form a source and a drain in the substrate on the respective sides of the gate.

According to the aforesaid method of fabricating a semiconductor device with a capacitor therein in the embodiment of the present invention, before performing the ion implant process, further includes forming spacers on the sidewalls of the gate.

According to the aforesaid method of fabricating a semiconductor device with a capacitor therein in the embodiment of the present invention, after performing the ion implant process, further includes forming an inter-layer dielectric (ILD) layer over the substrate to cover the capacitor and forming a plurality of contacts in the ILD layer such that the contacts are connected to the bottom conductive layer, the top conductive layer and the contact region respectively.

According to the aforesaid method of fabricating a semiconductor device with a capacitor therein in the embodiment of the present invention, the second bottom diffusion region is an N-well and the first bottom diffusion region is a P-well, for example.

According to the aforesaid method of fabricating a semiconductor device with capacitor therein in the embodiment of the present invention, the bottom conductive layer and the top conductive layer can be fabricated using polysilicon, for example.

According to the aforesaid method of fabricating a semiconductor device with capacitor therein in the embodiment of the present invention, the first dielectric layer and the second dielectric layer can be an oxide layer, a silicon nitride layer or an oxide/nitride/oxide (ONO) layer.

The present invention also provides a silicon-on-insulator semiconductor capacitor comprising a substrate, a silicon-on-insulator (SOI) layer, a diffusion region, a first dielectric layer, a bottom conductive layer, a second dielectric layer and a top conductive layer. The SOI layer is located over the substrate; the diffusion region is located in the SOI layer; the first dielectric layer is located over the diffusion region; the bottom conductive layer is located over the first dielectric layer; the second dielectric layer is located over the bottom conductive layer; and, the top conductive layer is located over the second conductive layer. The diffusion region, the first dielectric layer, the bottom conductive layer, the second dielectric layer and the top conductive layer together form a capacitor.

According to the aforesaid SOI semiconductor capacitor in the embodiment of the present invention, the bottom conductive layer and the top conductive layer can be fabricated using polysilicon, for example.

According to the aforesaid SOI semiconductor capacitor in the embodiment of the present invention, the first dielectric layer and the second dielectric layer can be an oxide layer, a silicon nitride layer or an oxide/nitride/oxide (ONO) layer.

According to the aforesaid SOI semiconductor capacitor in the embodiment of the present invention, the capacitor further includes a contact region in the diffusion region beside the capacitor. The contact region and the diffusion region have the same conductivity. Furthermore, the SOI semiconductor capacitor further includes an inter-layer dielectric (ILD) layer above the SOI layer and covering the capacitor and a plurality of contacts in the ILD layer that connects with the bottom conductive layer, the top conductive layer and the contact region respectively.

According to the aforesaid SOI semiconductor capacitor in the embodiment of the present invention, the diffusion region is an N-type diffusion region, for example.

The present invention also provides an alternative method of fabricating a silicon-on-insulator (SOI) semiconductor capacitor. First, a substrate is provided. The substrate has a SOI layer formed thereon. Then, a diffusion region is formed in the SOI layer. Thereafter, a first dielectric layer is formed over the SOI layer. After that, a first conductive layer is formed over the first dielectric layer. The first conductive layer is patterned to form a bottom conductive layer. Next, a second dielectric layer is formed on the surface of the bottom conductive layer. Then, a second conductive layer is formed over the second dielectric layer. The second conductive layer is patterned to define a top conductive layer. The diffusion region, the first dielectric layer, the bottom conductive layer, the second dielectric layer and the top conductive layer together form a capacitor.

According to the aforesaid method of fabricating a SOI semiconductor capacitor in the embodiment of the present invention, after patterning the second conductive layer, further includes performing an ion implant process to form a contact region in the diffusion region beside the capacitor. The contact region and the diffusion region have the same conductivity type.

According to the aforesaid method of fabricating a SOI semiconductor capacitor in the embodiment of the present invention, after performing the ion implant process, further includes forming an inter-layer dielectric (ILD) layer over the SOI layer to cover the capacitor. Furthermore, a plurality of contacts is formed in the ILD layer such that the contacts are connected to the bottom conductive layer, the top conductive layer and the contact region respectively.

According to the aforesaid method of fabricating a SOI semiconductor capacitor in the embodiment of the present invention, the bottom conductive layer and the top conductive layer are fabricated using polysilicon, for example.

According to the aforesaid method of fabricating a SOI semiconductor capacitor in the embodiment of the present invention, the first dielectric layer and the second dielectric layer can be an oxide layer, a silicon nitride layer or an oxide/nitride/oxide (ONO) layer.

According to the aforesaid method of fabricating a SOI semiconductor capacitor in the embodiment of the present invention, the diffusion region is an N-type diffusion region, for example.

The present invention also provides a semiconductor capacitor comprising a substrate, an isolation structure, a first conductive layer, a first dielectric layer, a second conductive layer, a second dielectric layer and a third conductive layer. The isolation structure is located in the substrate; the first conductive layer is located over the isolation structure; the first dielectric layer is located over the first conductive layer; the second conductive layer is located over the first dielectric layer; the second dielectric layer is located over the second conductive layer; and, the third conductive layer is located over the second dielectric layer. The first conductive layer, the first dielectric layer, the second conductive layer, the second dielectric layer and the third conductive layer together form a capacitor.

According to the aforesaid semiconductor capacitor in the embodiment of the present invention, the first conductive layer, the second conductive layer and the third conductive layer are fabricated using polysilicon, for example.

According to the aforesaid semiconductor capacitor in the embodiment of the present invention, the first dielectric layer and the second dielectric layer can be an oxide layer, a silicon nitride layer or an oxide/nitride/oxide (ONO) layer.

According to the aforesaid semiconductor capacitor in the embodiment of the present invention, the capacitor further includes an inter-layer dielectric (ILD) layer over the substrate to cover the capacitor and a plurality of contacts in the ILD layer that connects with the first conductive layer, the second conductive layer and the third conductive layer respectively.

According to the aforesaid semiconductor capacitor in the embodiment of the present invention, the isolation structure includes a shallow trench isolation (STI) structure, for example.

The present invention also provides a method of fabricating a semiconductor capacitor. First, a substrate having an isolation structure therein is provided. Then, a first conductive layer is formed over the isolation structure. Thereafter, a first dielectric layer is formed over the first conductive layer and then a second conductive layer is formed over the first dielectric layer. After that, a second dielectric layer is formed over the second conductive layer and then a third conductive layer is formed over the second dielectric layer. The first conductive layer, the first dielectric layer, the second conductive layer, the second dielectric layer and the third conductive layer together form a capacitor.

According to the aforesaid method of fabricating a semiconductor capacitor in the embodiment of the present invention, after forming the third conductive layer over the second dielectric layer, further includes forming an inter-layer dielectric (ILD) layer over the substrate to cover the capacitor and forming a plurality of contacts in the ILD layer such that the contacts are connected to the first conductive layer, the second conductive layer and the third conductive layer respectively.

According to the aforesaid method of fabricating a semiconductor capacitor in the embodiment of the present invention, the first conductive layer, the second conductive layer and the third conductive layer are fabricated using polysilicon, for example.

According to the aforesaid method of fabricating a semiconductor capacitor in the embodiment of the present invention, the first dielectric layer and the second dielectric layer can be an oxide layer, a silicon nitride layer or an oxide/nitride/oxide (ONO) layer.

According to the aforesaid method of fabricating a semiconductor capacitor in the embodiment of the present invention, the isolation structure includes a shallow trench isolation (STI) structure, for example.

In the present invention, a capacitor comprising three conductive layers separated by two dielectric layers is provided. Hence, a higher per unit area capacitance than a conventional capacitor is obtained so that more space is available for the design area. Moreover, a different capacitance can be obtained by adjusting the thickness of the oxide layer. In other words, the capacitance of the capacitor can be modified by a simple adjustment. And, the MOS transistor Vt can free from the influence of the voltage provided to the capacitor. Furthermore, it doesn't need other mask to form the capacitor of the present invention.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a schematic cross-sectional view of a conventional capacitor.

FIG. 2 is a schematic cross-sectional view of a semiconductor device having a capacitor according to one embodiment of the present invention.

FIGS. 3A through 3F are schematic cross-sectional views showing the steps for fabricating a semiconductor device having a capacitor according to one embodiment of the present invention.

FIG. 4 is a schematic cross-sectional view showing the structure of a silicon-on-insulator semiconductor capacitor according to another embodiment of the present invention.

FIGS. 5A through 5C are schematic cross-sectional views showing the steps for fabricating a silicon-on-insulator semiconductor capacitor according to anther embodiment of the present invention.

FIG. 6 is a schematic cross-sectional view showing the structure of a capacitor for a semiconductor device according to yet another embodiment of the present invention.

FIGS. 7A through 7C are schematic cross-sectional views showing the steps for fabricating a capacitor for a semiconductor device according to yet another embodiment of the present invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

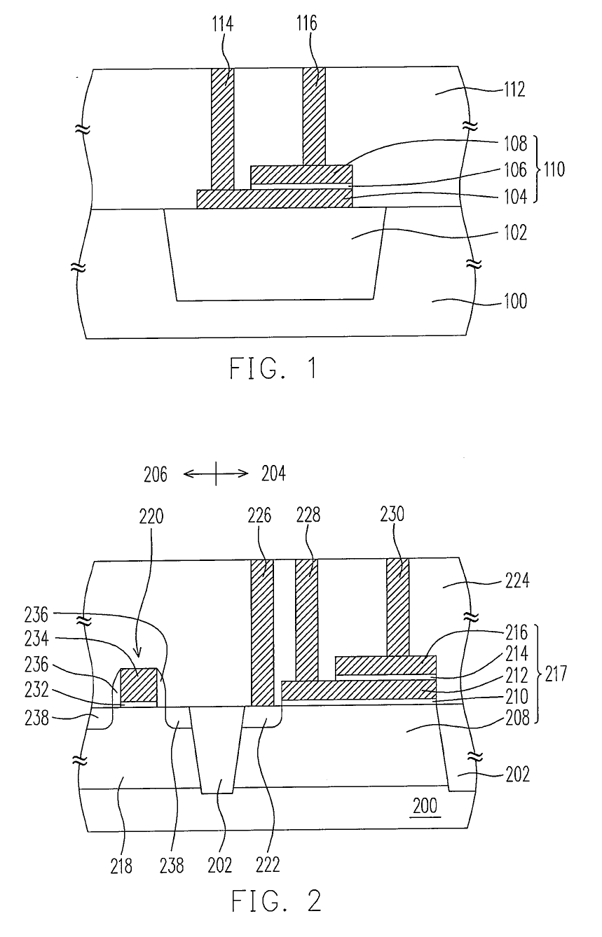

FIG. 2 is a schematic cross-sectional view of a semiconductor device having a capacitor according to one embodiment of the present invention. As shown in FIG. 2, the structure in the present embodiment includes a substrate 200, a capacitor 217 and a metal-oxide-semiconductor (MOS) transistor 220. The MOS transistor 220 is located in a MOS transistor region 206 of the substrate 200, and the MOS transistor region 206 has a first bottom diffusion region 218. The capacitor 217 is located in a capacitor region 204 of the substrate 200 and consisted of a second bottom diffusion region 208, a first dielectric layer 210, a bottom conductive layer 212, a second dielectric layer 214 and a top conductive layer 216, wherein the second bottom diffusion region 208 and the first bottom diffusion region 218 are different conductive type. The first bottom diffusion region 218 can be an P-well region and the second bottom diffusion region 208 can be an N-well region, for example. The bottom conductive layer 212 and the top conductive layer 216 are fabricated using polysilicon or some other suitable material, for example. The dielectric layer 210 and the dielectric layer 214 are, for example oxide layers, silicon nitride layers or oxide/nitride/oxide (ONO) layers. The MOS transistor 220 is located over the first bottom diffusion region 218 within the MOS transistor region 206. The semiconductor device further includes an isolation structure 202 located in the substrate 200 to separate the MOS transistor region 206 and the capacitor region 204, for example.

As shown in FIG. 2, the MOS transistor 220 comprises a gate dielectric layer 232, a gate 234, a pair of spacers 236, a source and a drain 238. In addition, the present embodiment also includes a contact region 222, an inter-layer dielectric (ILD) layer 224 and a plurality of contacts 226, 228 and 230. The contact region 222 is a n+ region located in the second bottom diffusion region 208 beside the capacitor 217, for example. The ILD layer 224 is located above the substrate 200 to cover the capacitor 217. The contacts 226, 228 and 230 are connected to the contact region 222, the bottom conductive layer 212 and the top conductive layer 216.

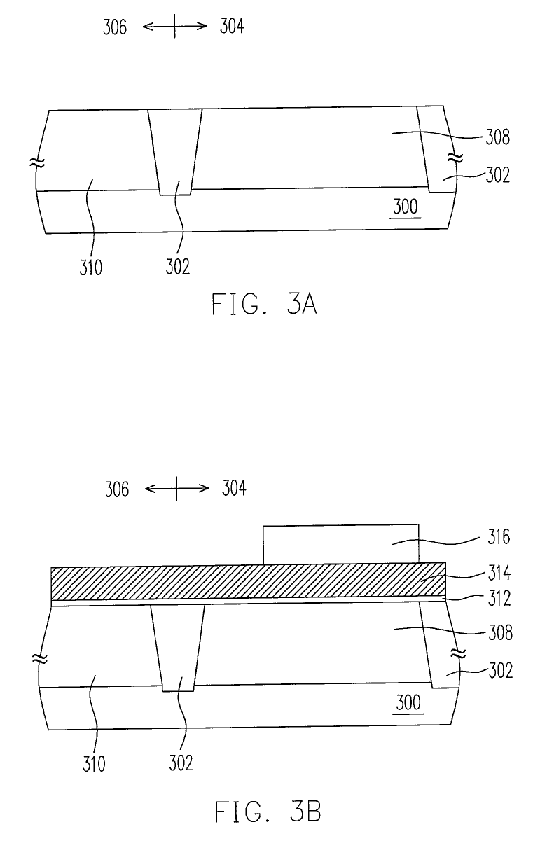

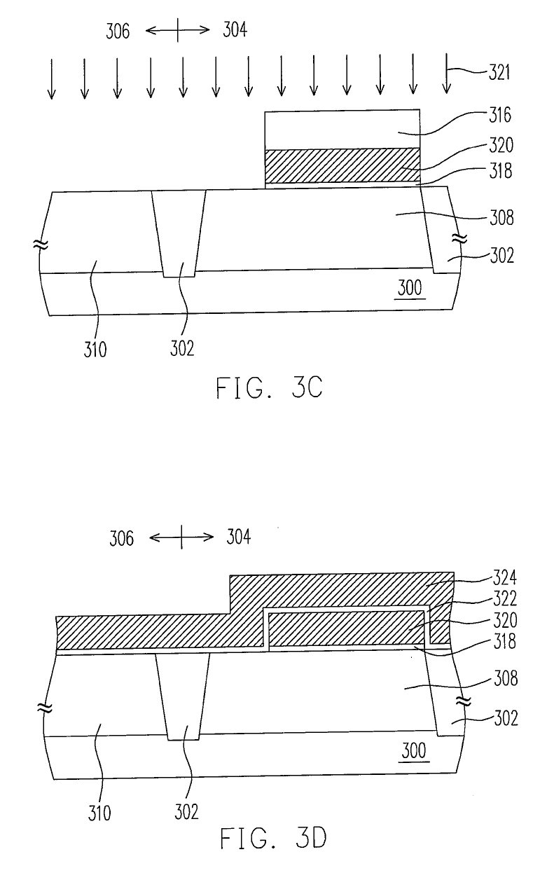

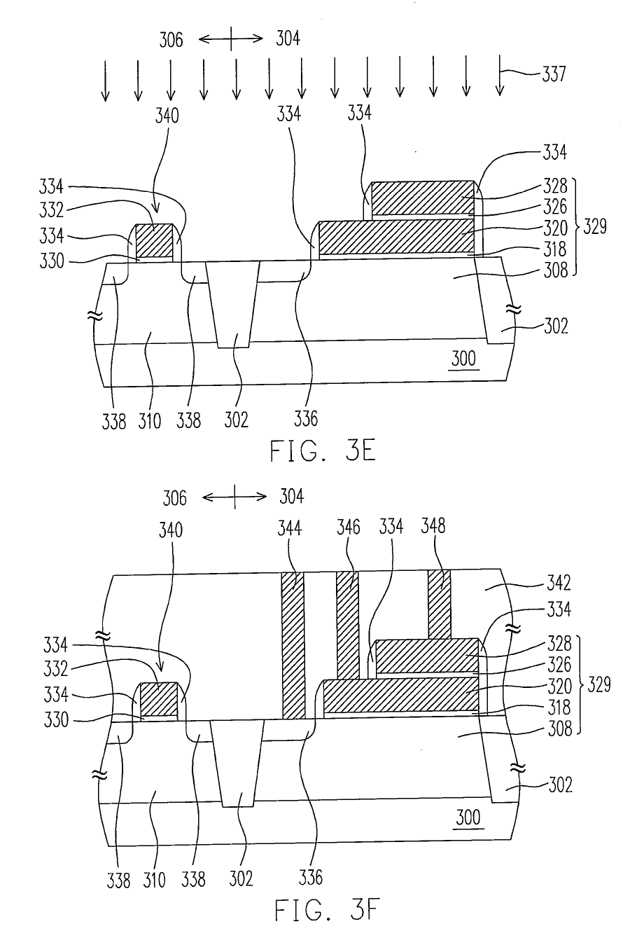

FIGS. 3A through 3F are schematic cross-sectional views showing the steps for fabricating a semiconductor device having a capacitor according to one embodiment of the present invention. First, as shown in FIG. 3A, a substrate 300 commonly having an isolation structure 320 thereon is provided. The isolation structure 302 separates the substrate 300 into a capacitor region 304 and a MOS transistor region 306. Then, a first bottom diffusion region 310 is formed in the substrate within the MOS transistor region 306 and a second bottom diffusion region 308 is formed in the substrate 300 within the capacitor region 304, respectively. The second bottom diffusion region 308 and the first bottom diffusion region 310 are different conductive type. The second bottom diffusion region 308 is an N-well region and the first bottom diffusion region 310 is a P-well region, for example.

As shown in FIG. 3B, a dielectric layer 312 is formed over the substrate 300. The dielectric layer 312 is an oxide layer, a silicon nitride layer or an oxide/nitride/oxide (ONO) layer formed, for example, by performing a thermal oxidation process. Then, a conductive layer 314 is formed over the dielectric layer 312. The conductive layer 314 is fabricated using polysilicon or some other suitable material and formed by performing a chemical vapor deposition process, for example. Thereafter, a patterned mask layer 316 is formed over the conductive layer 314 to expose the MOS transistor region and a portion of the conductive layer 314 is the capacitor region 304.

As shown in FIG. 3C, using the patterned mask layer 316 as a mask, the exposed conductive layer 314 and the exposed dielectric layer 312 are removed so that only the bottom conductive layer 320 and the dielectric layer 318 in the capacitor region 304 remain. The method of removing the conductive layer 314 and the dielectric layer 312 includes performing a dry etching operation, for example. Then, using the patterned mask layer 316 as a mask again, a threshold voltage (Vt) adjustment implant process 321 is carried out to adjust the voltage of the substrate 300 before forming the NMOS transistor. However, the area set aside for forming the PMOS transistor must be covered with a mask first. Thereafter, the patterned mask layer 316 is removed.

After removing the patterned mask layer 316, another threshold voltage (Vt) adjustment implant process (not shown) can be carried out similar to the one in FIG. 3C. The only difference is that the covered area is the NMOS transistor and the capacitor region 304 and the area undergoing the threshold voltage adjustment implant process is now the PMOS area.

As shown in FIG. 3D, a dielectric layer 322 is formed on the surface of the substrate 300 and the bottom conductive layer 320. The dielectric layer 322 is an oxide layer, a silicon nitride layer or an oxide/nitride/oxide (ONO) layer formed by performing a thermal oxidation process, for example. Then, a conductive layer 324 is formed over the dielectric layer 322. The conductive layer 324 is fabricated using polysilicon or some other suitable material and formed by performing a chemical vapor deposition process, for example.

As shown in FIG. 3E, the conductive layer 324 is patterned to define a top conductive layer 328 in the capacitor region 304 and a gate 332 in the MOS transistor region 306. The second bottom diffusion region 308, the dielectric layer 318, the bottom conductive layer 320, the dielectric layer 326 and the top conductive layer 328 together form a capacitor 329. Then, spacers 334 are formed on the sidewalls of the gate 332. Simultaneously, spacers 334 are also formed on the sidewalls of the capacitor 329. The method of forming the spacers 334 includes forming a silicon nitride layer over the MOS transistor 340 and the capacitor 329 on the substrate 300 and then etching back the silicon nitride layer to form the spacers 334. Thereafter, an ion implant process 337 is carried out to form a contact region 336 in the second bottom diffusion region 308 beside the capacitor 329 and a source and a drain 338 in the substrate 300 on the respective sides of the gate 332.

As shown in FIG. 3F, an inter-layer dielectric (ILD) layer 342 is formed over the substrate 300 to cover the capacitor 329 and the MOS transistor 340. Then, a plurality of contacts 344, 346, 348 is formed in the ILD layer 342. The contacts 344, 346, 348 are electrically connected to the contact region 336, the bottom conductive layer 320 and the top conductive layer 328.

The capacitor 329 in the present invention has a five-layered structure comprising the second bottom diffusion region 308, the dielectric layer 318, the bottom conductive layer 320, the dielectric layer 326 and the top conductive layer 328. This five-layered structure is capable of increasing the capacitance of the capacitor 329. Furthermore, different capacitance for the capacitor 329 can be obtained by setting the thickness of the oxide layer. In addition, the space on a wafer necessary for accommodating the capacitor can be reduced. Moreover, the MOS transistor Vt can free from the influence of the voltage provided to the capacitor. And, the capacitor of the present invention can be formed without additional mask.

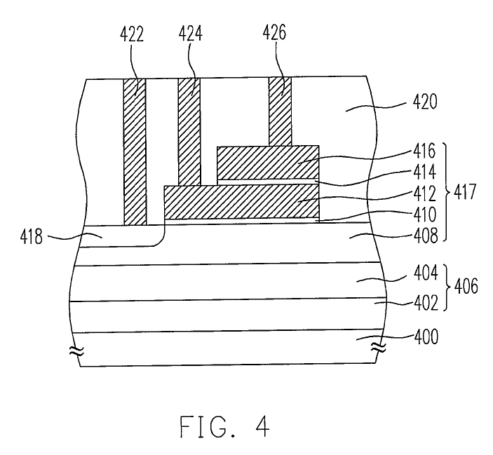

FIG. 4 is a schematic cross-sectional view showing the structure of a silicon-on-insulator semiconductor capacitor according to another embodiment of the present invention. As shown in FIG. 4, the structure in the present embodiment includes a substrate 400, a silicon-on-insulator (SOI) layer 406, a diffusion region 408, a dielectric layer 410, a bottom conductive layer 412, a dielectric layer 414 and a top conductive layer 416. The SOI layer 406 is located over the substrate 400. The SOI layer 406 comprises an insulation layer 402 and a silicon layer 404, for example. The diffusion region 408 is formed in the SOI layer 406. The diffusion region 408 is an N-type diffusion region, for example. The dielectric layer 410 is located over the diffusion region 408; the bottom conductive layer 412 is located over the dielectric layer 410; the dielectric layer 414 is located over the bottom conductive layer; and, the top conductive layer 416 is located over the dielectric layer 414. The diffusion region 408, the dielectric layer 410, the bottom conductive layer 412, the dielectric layer 414 and the top conductive layer together form a capacitor 417. The bottom conductive layer 412 and the top conductive layer 416 are fabricated using polysilicon or other suitable material, for example. The dielectric layer 410 and the dielectric layer 414 are oxide layers, silicon nitride layers or oxide/nitride/oxide (ONO) layer, for example.

As shown in FIG. 4, the structure in the present embodiment further includes a contact region 418, an inter-layer dielectric (ILD) layer 420 and a plurality of contacts 422, 424 and 426. The contact region 418 is located in the diffusion region 408 beside the capacitor 417. The contact region 418 and the diffusion region 408 have of the same conductivity type. The ILD layer 420 is located over the SOI layer 405 and covering the capacitor 417. The contacts 422, 424, 426 are connected to the contact region 418, the bottom conductive layer 412 and the top conductive layer 416 respectively.

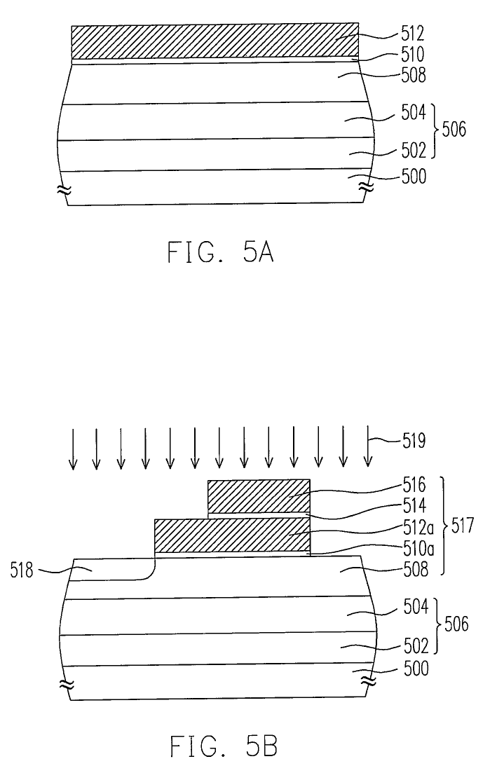

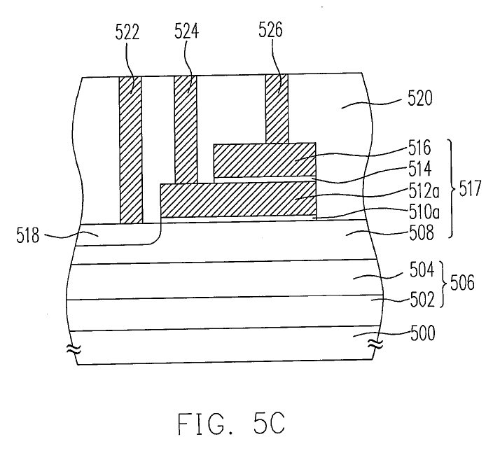

FIGS. 5A through 5C are schematic cross-sectional views showing the steps for fabricating a silicon-on-insulator semiconductor capacitor according to anther embodiment of the present invention. As shown in FIG. 5A, a substrate having a silicon-on-insulator (SOI) layer 506 thereon is provided. The SOI layer 506 comprises an insulating layer 503 and a silicon layer 504 formed, for example, by performing an oxygen implant process or a wafer bonding process. Then, a diffusion region 508 is formed in the SOI layer 506. The diffusion region 508 is an N-type diffusion region, for example. Thereafter, a dielectric layer 510 is formed over the SOI layer 506. The dielectric layer 510 is an oxide layer, silicon nitride layer or an oxide/nitride/oxide (ONO) layer formed, for example, by performing a thermal oxidation. After that, a conductive layer 512 is formed over the dielectric layer 510. The conductive layer 512 is a polysilicon layer formed by performing a chemical vapor deposition process, for example.

As shown in FIG. 5B, using a patterned mask layer (not shown) as a mask, the conductive layer 512 and the dielectric layer 510 are patterned to remove the exposed conductive layer 512 and the dielectric layer 510 to form a bottom conductive layer 512a and a dielectric layer 510a. The method of removing the conductive layer 512 and the dielectric layer 510 includes performing a dry etching process, for example. Then, a dielectric layer 514 and a top conductive layer 516 are sequentially formed on the surface of the bottom conductive layer 512a. The dielectric layer 514 and the top conductive layer 516 are fabricated, for example, using the same material and method as the one for forming the dielectric layer 510a and the bottom conductive layer 512a and hence a detailed description is omitted. The diffusion region 508, the dielectric layer 510a, the bottom conductive layer 512a, the dielectric layer 514 and the top conductive layer 516 together form a capacitor 517. Thereafter, an ion implant process 519 is performed to form a contact region 518 in the diffusion region 508 beside the capacitor 517. The contact region 518 and the diffusion region 508 have the same conductivity type.

As shown in FIG. 5C, an inter-layer dielectric (ILD) layer 520 is formed over the SOI layer 506 for covering the capacitor 517. Then, a plurality of contacts 522, 524, 526 is formed in the ILD layer 520 such that the contacts 522, 524, 526 are connected to the contact region 518, the bottom conductive layer 512a and the top conductive layer 516 respectively. The method of fabricating the contacts includes forming a patterned mask layer over the ILD layer 342 and dry-etching the ILD layer 520 using the patterned mask layer as a mask until conductive layer or contact layer that needs to be connected is reached. After that, conductive material is deposited over the contact area to form a conductive layer. The conductive layer is a doped polysilicon layer or a tungsten layer formed by performing a chemical vapor deposition process, for example.

The capacitor 517 in the present invention has a five-layered structure including, in sequential order, the diffusion region 508, the dielectric layer 510a, the bottom conductive layer 512a, the dielectric layer 514 and the top conductive layer 516. The capacitor 517 with this structure has a larger capacitance than the conventional capacitor. Furthermore, a different capacitance value can be obtained by setting the thickness of the oxide layer. Moreover, with the increase in capacitance, the space that must be set aside for accommodating the capacitor can be reduced.

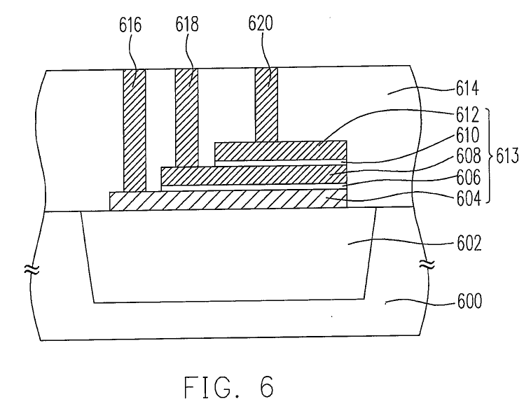

FIG. 6 is a schematic cross-sectional view showing the structure of a capacitor for a semiconductor device according to yet another embodiment of the present invention. As shown in FIG. 6, the structure in the present invention includes a substrate 600, an isolation structure 602, a conductive layer 604, a dielectric layer 606, a conductive layer 608, a dielectric layer 610 and a conductive layer 612. The isolation structure 602 is located in the substrate 600. The isolation structure 602 is a shallow trench isolation (STI) structure, for example. The conductive layer 604 is located over the isolation structure 602; the dielectric layer 606 is located over the conductive layer 604; the conductive layer 608 is located over the dielectric layer 606; the dielectric layer 610 is located over the conductive layer 608; and, the conductive layer 612 is located over the dielectric layer 610. The conductive layer 604, the dielectric layer 606, the conductive layer 608, the dielectric layer 610 and the conductive layer 612 together form a capacitor 613. The conductive layer 604, the conductive layer 608 and the conductive layer 612 are fabricated using polysilicon or other suitable material, for example. The dielectric layer 606 and the dielectric layer 610 are oxide layers, silicon nitride layers or oxide/nitride/oxide (ONO) layers, for example.

In addition, the semiconductor capacitor further includes an inter-layer dielectric (ILD) layer 614 on the substrate 600 covering the capacitor 613 and a plurality of contacts 616, 618 and 620 in the IDL layer 614. Furthermore, these contacts are connected to the conductive layer 604, the conductive layer 608 and the conductive layer 612 respectively.

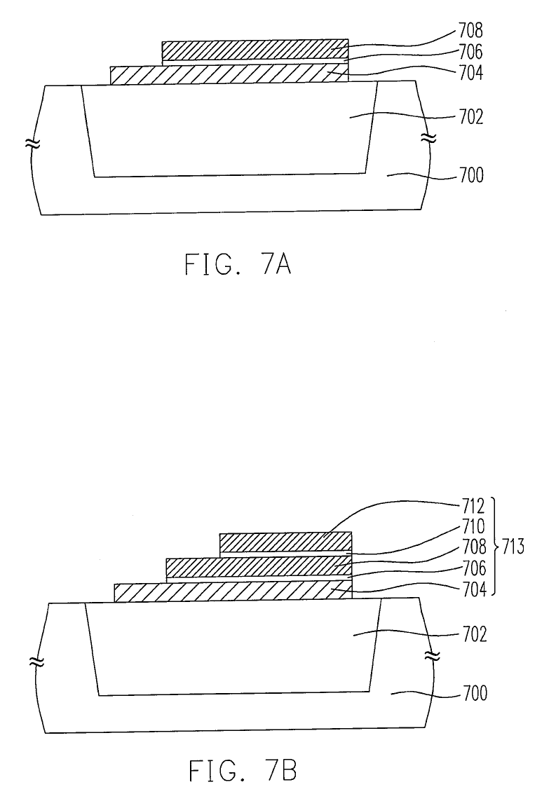

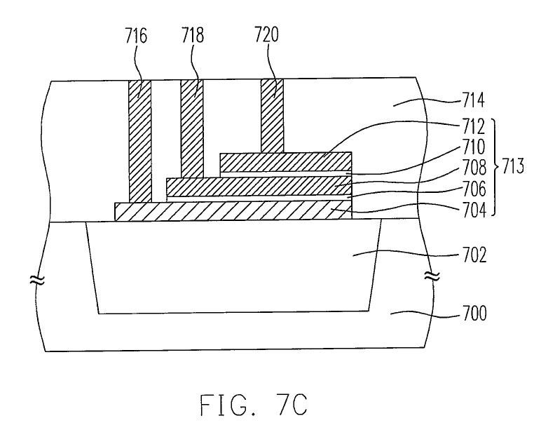

FIGS. 7A through 7C are schematic cross-sectional views showing the steps for fabricating a capacitor for a semiconductor device according to yet another embodiment of the present invention. As shown in FIG. 7A, a substrate 700 having an isolation structure 702 thereon is provided. The isolation structure 702 is a shallow trench isolation (STI) structure, for example. Then, a conductive layer 704 is formed over the isolation structure 702. Thereafter, a dielectric layer and a conductive layer (not shown) are formed over the conductive layer 704. The dielectric layer is an oxide layer, a silicon nitride layer or an oxide/nitride/oxide (ONO) layer formed by performing a thermal oxidation process, for example. The conductive layer is a polysilicon layer or other suitable material layer formed by performing a chemical vapor deposition process, for example. After that, a patterned mask layer (not shown) is formed over the conductive layer. Using the patterned mask layer as a mask, the exposed conductive layer and dielectric layer are removed to form a conductive layer 708 and a dielectric layer 706. The method of removing the exposed conductive layer and the dielectric layer includes performing a dry etching operation, for example.

As shown in FIG. 7B, a dielectric layer 710 and a conductive layer 712 are formed over the conductive layer 708. The material and method for forming the dielectric layer 710 and the conductive layer 712 are identical to the one for forming the dielectric layer 706 and the conductive layer 708 and hence a detailed description is not repeated here. The conductive layer 704, the dielectric layer 706, the conductive layer 708, the dielectric layer 710 and the conductive layer 712 together form a capacitor 713.

As shown in FIG. 7C, an inter-layer dielectric (ILD) layer 714 is formed over the substrate 700 to cover the capacitor 713. Then, a plurality of contacts 716, 718, 720 is formed in the ILD layer 714. The contacts 716, 718, 720 are connected to the conductive layer 704, the conductive layer 708 and the conductive layer 712 respectively. The method of forming the contacts 716, 718, 720 includes forming a patterned mask layer (not shown) over the ILD layer and dry etching the ILD layer using the patterned mask layer as a mask until the conductive layer that need to be connected is reached. Thereafter, conductive material is deposited into the contact area to form a conductive layer. The conductive layer is a doped polysilicon layer or a tungsten layer formed by performing a chemical vapor deposition process, for example.

The capacitor 729 in the present invention has a five-layered structure comprising the conductive layer 704, the dielectric layer 706, the conductive layer 708, the dielectric layer 710 and the conductive layer 712. This five-layered structure is capable of increasing the capacitance of the capacitor 329. Furthermore, different capacitance for the capacitor 329 can be obtained by setting the thickness of the oxide layer. In addition, the space on a wafer necessary for accommodating the capacitor can be reduced.

In summary, the capacitor of the present invention has at least the following advantages:

1. The capacitor in the present invention is a five layer of structure, so a per unit area capacitance is much higher than the conventional capacitor and hence can save more design area.

2. The capacitor according to the present application is flexible to get different capacitance depended on the thickness of the dielectric layer. In other words, the capacitor has a modifiable capacitance.

3. When the present application is applied to a device with MOS transistor, the MOS transistor Vt can free from the influence of the voltage provided to the capacitor due to the different conductive type between the bottom diffusion regions of the MOS transistor region and the capacitor regin.

4. The method to form the five-layered capacitor of the present invention can integrates with prior process, so it doesn't need additional mask to form the structure.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of fabricating a semiconductor device with a capacitor, comprising the steps of:
providing a substrate having an isolation structure for separating the substrate into a capacitor region and a MOS transistor region;
forming a first bottom diffusion region and a second bottom diffusion region in the substrate within the MOS transistor region and the capacitor region respectively, wherein the second bottom diffusion region and the first bottom diffusion region are different conductive type;
forming a first dielectric layer over the substrate;
forming a first conductive layer over the first dielectric layer;
forming a patterned mask layer over the first conductive layer to expose the MOS transistor region and a portion of the first conductive layer in the capacitor region;
removing the exposed first conductive layer and the first dielectric layer using the patterned mask layer as a mask to form a bottom conductive layer in the capacitor region;
performing a threshold voltage (Vt) adjustment implant process using the patterned mask layer as a mask;
removing the patterned mask layer;
forming a second dielectric layer on the surface of the substrate and on the surface of the bottom conductive layer;
forming a second conductive layer over the second dielectric layer; and
patterning the second conductive layer to define a top conductive layer in the capacitor region and a gate in the MOS transistor region, wherein the second bottom diffusion region, the first dielectric layer, the bottom conductive layer, the second dielectric layer and the top conductive layer together form a capacitor.

2. The method of claim 1, wherein after patterning the second conductive layer, further comprises performing an ion implant process to form a contact region in the second bottom diffusion region and a source and a drain in the substrate on the respective sides of the gate.

3. The method of claim 2, wherein before performing the ion implant process, further comprises forming spacers on the sidewalls of the gate.

4. The method of claim 2, wherein after performing the ion implant process, further comprises:
forming an inter-layer dielectric (ILD) layer over the substrate to cover the capacitor; and
forming a plurality of contacts in the ILD layer such that the contacts are connected to the bottom conductive layer, the top conductive layer and the contact region.

5. The method of claim 1, wherein the second bottom diffusion region comprises an N-well region and the first bottom diffusion region comprises a P-well region.

6. The method of claim 1, wherein the material constituting the bottom conductive layer and the top conductive layer comprises polysilicon.

7. The method of claim 1, wherein the first dielectric layer and the second dielectric layer comprise an oxide layer, a silicon nitride layer or an oxide/nitride/oxide (ONO) layer.

8. A method of fabricating a silicon-on-insulator (SOI) semiconductor capacitor, comprising the steps of:
providing a substrate, wherein the substrate has a SOI layer formed thereon;
forming a diffusion region in the SOI layer;
forming a first dielectric layer over the SOI layer;
forming a first conductive layer over the first dielectric layer;
patterning the first conductive layer to form a bottom conductive layer;
forming a second dielectric layer on the surface of the bottom conductive layer;
forming a second conductive layer over the second dielectric layer; and
patterning the second conductive layer to define a top conductive layer, wherein the diffusion region, the first dielectric layer, the bottom conductive layer, the second dielectric layer and the top conductive layer together form a capacitor.

9. The method of claim 8, wherein after patterning the second conductive layer, further comprises performing an ion implant process to form a contact region in the diffusion region beside the capacitor such that the contact region and the diffusion region has the same conductivity type.

10. The method of claim 9, wherein the step of performing the ion implant process further comprises:
forming an inter-layer dielectric (ILD) layer to cover the capacitor; and
forming a plurality of contacts in the ILD layer, wherein the contacts are connected to the bottom conductive layer, the top conductive layer and the contact region respectively.

11. The method of claim 8, wherein the material constituting the bottom conductive layer and the top conductive layer comprises polysilicon.

12. The method of claim 8, wherein the first dielectric layer and the second dielectric layer comprises an oxide layer, a silicon nitride layer or an oxide/nitride/oxide (ONO) layer.

13. The method of claim 8, wherein the diffusion region comprises an N-type diffusion region.

14. A method of fabricating a capacitor for a semiconductor device, comprising the steps of:
providing a substrate having an isolation structure formed thereon;
forming a first conductive layer over the isolation structure;
forming a first dielectric layer over the first conductive layer;
forming a second conductive layer over the first dielectric layer;
forming a second dielectric layer over the second conductive layer; and
forming a third conductive layer over the second dielectric layer, wherein the first conductive layer, the first dielectric layer, the second conductive layer, the second dielectric layer and the third conductive layer together form the capacitor.

15. The method of claim 14, wherein after forming the third conductive layer over the second dielectric layer, further comprises:
forming an inter-layer dielectric (ILD) layer over the substrate to cover the capacitor; and
forming a plurality of contacts in the ILD layer, wherein the contacts are connected to the first conductive layer, the second conductive layer and the third conductive layer.

16. The method of claim 14, wherein the material constituting the first conductive layer, the second conductive layer and the third conductive layer comprises polysilicon.

17. The method of claim 14, wherein the first dielectric layer and the second dielectric layer comprises an oxide layer, a silicon nitride layer or an oxide/nitride/oxide (ONO) layer.

18. The method of claim 14, wherein the isolation structure comprises a shallow trench isolation (STI) structure.
